(19) United States
(12) Patent Application Publication
(10) Pub. No.: US 2007/0151601 A1
(43) Pub. Date: Jul. 5, 2007

(54) Semiconductor electrode using carbon nanotube, preparation method thereof, and solar cell comprising the same

(76) Inventors: Won Cheol Jung, Seoul (KR); Jin Gyu Lee, Seoul (KR); Jung Gyu Nam, Yongin-si (KR); Sang Cheol Park, Seoul (KR); Young Jun Park, Suwon-si (KR); Byung Hee Sohn, Yongin-si (KR); Eun Sung Lee, Seoul (KR)

Correspondence Address: CANTOR COLBURN, LLP, 55 GRIFFIN ROAD SOUTH, BLOOMFIELD, CT, 06002, US

(21) Appl. No.: 11/507,420

(22) Filed: Aug. 21, 2006

(30) Foreign Application Priority Data
Dec. 29, 2005 (KR) 10-2005-0133671

(51) Int. Cl. H01L 31/00

(52) U.S. Cl. 136/263; 977/745; 977/948

(57) ABSTRACT

Disclosed herein is a semiconductor electrode including a layer of metal oxide particles; a dye coating a surface of the layer of metal oxide particles; and a carbon nanotube, having at least one anchoring functional group, attached to the layer of metal oxide particles through the anchoring functional group. Also disclosed are a method for preparing the semiconductor electrode and a solar cell including the semiconductor electrode.

### CROSS-REFERENCE TO RELATED PATENT APPLICATIONS

This application claims priority to Korean Patent Application No. 2005-133671, filed on Dec. 29, 2005, and all the benefits accruing therefrom under 35 U.S.C. §119(a), the contents of which are herein incorporated by reference in its entirety.

### BACKGROUND OF THE INVENTION

1. Field of the Invention

The present invention relates to a semiconductor electrode. More particularly, the present invention relates to a semiconductor electrode that includes a photosensitive dye-adsorbed metal oxide layer on which a carbon nanotube is anchored through an anchoring functional group conjugated therewith. Also, the present invention relates to a method of preparing the semiconductor electrode and a solar cell comprising the semiconductor electrode.

2. Description of the Related Art

A solar cell, which is a photovoltaic device for converting sunlight into electrical energy, taps an unlimited energy source, is more environmentally friendly than many other energy sources, and has become increasingly more important over time. Particularly, when employing solar cells, portable information devices such as portable computers, mobile phones, and personal digital assistants, can be charged and operated using only sunlight.

Monocrystalline and polycrystalline silicon-based solar cells are more prevalent than other types of solar cells. However, silicon-based solar cells can be disadvantageous in that they require elaborate apparatuses and expensive materials for the manufacture thereof, leading to increased production costs, and in that the conversion efficiency of solar energy into electrical energy has been difficult to improve.

One alternative to silicon-based solar cells is an organic material-based solar cell that can be produced at low cost. In particular, significant attention is being paid to dye-sensitized solar cells because of their low production costs. Dye-sensitized solar cells, which comprise one type of photoelectrochemical solar cell, utilize photo-sensitization of metal oxide semiconductors. The cells have a simple structure that generally includes a semiconductor electrode made from dye-adsorbed, highly porous, metal oxide, nanocrystalline particles deposited on a transparent electrically conductive substrate, and a counter electrode with an electrolyte interposed therebetween. The semiconductor electrode includes an electrically conductive transparent substrate, a metal oxide, and a light absorbing layer.

When sunlight is incident on a dye-sensitized solar cell, the dye absorbs photons and becomes excited. An electron in the excited state of the dye molecule is injected from the dye into the conduction band of the metal oxide. Electrons in the conduction band of the semiconductor flow through an external circuit to the counter electrode. Through this process, radiant energy is converted into electricity.

However, not all of the excited electrons injected into the conduction band reach the counter electrode. There often occurs electron back-transfer, which is the thermal reversal of excited state electrons restoring the donor and acceptor to their original oxidation states. That is, some of the excited electrons injected into the conduction band may combine with redox couples in the electrolyte, or some of the electrons in the excited state may recombine with the dye molecules to return to the ground state. This electron back-transfer causes the solar cell to decrease in photoelectric conversion efficiency, leading to a low electromotive force. Presently, electron back-transfer is a major obstacle to overcome in order to improve the electrical conductivity of the semiconductor electrode, and thus the photoelectric conversion efficiency.

One approach to overcoming this problem is a solar cell comprising, as a semiconductor electrode, a porous titanium dioxide thin film electrode onto which a C₁₀ or longer alkyl carbonic acid, along with a photosensitive dye, is adsorbed. This functions to block the interactions between dye molecules, thereby allowing the dye to sufficiently exhibit its intrinsic photosensitization ability, but does not prevent electron back-transfer. Thus, the solar cell is only slightly improved with respect to photoelectric conversion efficiency.

Alternatively, inserting a carbon nanotube between the transparent electrode and metal oxide has been proposed to reduce the interfacial resistance so as to increase the photoelectric conversion efficiency. However, naked carbon nanotubes cannot be associated directly with metal oxides, resulting in inefficient harvesting of electricity.

### BRIEF SUMMARY OF THE INVENTION

The present invention overcomes the above-described problems occurring in the prior art, and an aspect of the present invention includes providing a semiconductor electrode capable of preventing electrons in an excited state from undergoing electron back-transfer so as to improve photoelectric conversion efficiency.

Another aspect of the present invention includes providing a method for preparing the semiconductor electrode.

Still another aspect of the present invention includes providing a highly efficient solar cell employing the semiconductor electrode.

In accordance with an exemplary embodiment of the present invention, a semiconductor electrode includes a layer of metal oxide particles; a dye coating a surface of the layer of metal oxide particles; and a carbon nanotube, having at least one anchoring functional group, attached to the layer of metal oxide particles through the anchoring functional group.

In one embodiment of the semiconductor electrode, the carbon nanotube is selected from among single-walled carbon nanotubes, double-walled carbon nanotubes, triple-walled carbon nanotubes, quadruple-walled carbon nanotubes, carbon nanohorns, and carbon nanofibers.

In another embodiment of the semiconductor electrode, the layer of metal oxide particles includes titanium oxide, tungsten oxide, niobium oxide, hafnium oxide, indium oxide, tin oxide, zinc oxide, or a combination comprising at least one of the foregoing oxides.

In accordance with another exemplary embodiment of the present invention, a method for preparing a semiconductor electrode includes: forming a layer of metal oxide particles on a transparent electrode; attaching a carbon nanotube having at least one anchoring functional group to the surface of the layer of metal oxide particles, wherein the at least one anchoring functional group is selected from the group consisting of a carboxylic acid group, a phosphoric acid group, a sulfuric acid group, a salicylic acid group, and combinations thereof; and adsorbing a dye on a surface of the layer of metal oxide particles.

In an embodiment of the method, the attaching includes dispersing the carbon nanotube having the anchoring functional group in a solvent; and immersing in the dispersion of the carbon nanotube the transparent electrode having the layer of metal oxide particles formed thereon.

In a modification, the carbon nanotube dispersing is facilitated by ultrasonication, thermal treatment, or a combination comprising at least one of the foregoing.

Yet another exemplary embodiment of the present invention includes a solar cell, comprising the semiconductor electrode, an electrolyte layer, and a counter electrode.

### BRIEF DESCRIPTION OF THE DRAWINGS

The above and other aspects, features, and other advantages of the present invention are further illustrated by the following detailed description taken in conjunction with the accompanying drawings, in which:

FIG. 1 is a schematic plan view illustrating the structure of an exemplary embodiment of a semiconductor electrode according to the present invention;

FIG. 2 is a schematic cross-sectional view illustrating an exemplary embodiment of a semiconductor electrode according to the present invention;

FIGS. 3A through 3C are schematic illustrations of exemplary embodiments of carbon nanotubes with anchoring functional group conjugated thereto, for use in the present invention; and

FIG. 4 is a schematic cross-sectional view illustrating an exemplary embodiment of a dye-sensitized solar cell according to the present invention.

### DETAILED DESCRIPTION OF THE INVENTION

The present invention will now be described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood in the following disclosure of the present invention, that as used herein, the term “and/or” includes any and all combinations of one or more of the associated listed items. In addition, the singular forms “a”, “an” and “the” are intended to include the plural forms as well, unless the context clearly indicates otherwise. It will be further understood that the terms “comprise”, “comprises”, and “comprising,” when used in this specification, specify the presence of stated features, integers, steps, operations, elements, components, and/or combination of the foregoing, but do not preclude the presence and/or addition of one or more other features, integers, steps, operations, elements, components, groups, and/or combination of the foregoing. The use of the terms “first”, “second”, and the like, where included, are for purposes of distinguishing elements only, and therefore should not be considered as implying any particular order or sequence unless otherwise specified.

Unless otherwise defined, all terms (including technical and scientific terms) used herein have the same meaning as commonly understood by one of ordinary skill in the art to which this invention belongs. It will be further understood that terms such as those defined in commonly used dictionaries should be interpreted as having a meaning that is consistent with their meaning in the context of the relevant art and will not be interpreted in an idealized or overly formal sense unless expressly so defined herein.

In exemplary embodiments, a semiconductor electrode for use in solar cells comprises a transparent electrode formed on the substrate, a metal oxide layer on the transparent electrode, a dye adsorbed on the metal oxide layer, and a carbon nanotube attached to the surface of the metal oxide layer through the anchoring functional groups thereof. Any functional group, as long as it has affinity for a metal oxide, may be used as the anchoring functional group. Examples thereof include, but are not limited to carboxylic acid, phosphoric acid, sulfuric acid, and salicylic acid groups.

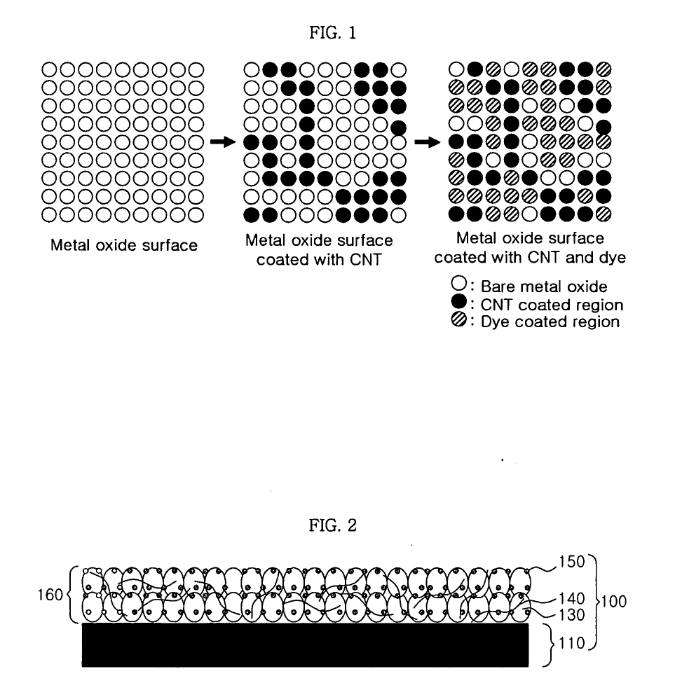

Referring now to FIG. 1 wherein the structure of an exemplary embodiment of the semiconductor electrode according to the present invention is shown schematically in a plan view. A carbon nanotube is anchored on the surface of a metal oxide layer through the anchoring functional group. Without this anchoring functional group, the carbon nanotube cannot be well adsorbed on the metal oxide because a naked carbon nanotube does not have an affinity for the metal oxide.

In addition, the introduction of a carbon nanotube on the metal oxide layer is advantageous in that electrons excited along the carbon nanotube can be more effectively transferred to the electrode. The transfer of electrons or holes may be interrupted at boundaries between metal oxide grains. The carbon nanotube anchored to the metal oxide layer causes electrons or holes to be transferred without interruption at grain boundaries.

Further, if the surface of the semiconductor electrode is treated with a carbon nanotube having an anchoring functional group, the electrons collected in the conduction band of the metal oxide are blocked from migrating into oxidized redox couples or dye molecules to increase short-cut photocurrent density (I_{sc}), which results in an improvement in the photoelectric conversion of a solar cell having the semiconductor electrode of the present invention.

FIG. 2 shows an exemplary embodiment of a semiconductor electrode according to the present invention in a schematic cross sectional view. The semiconductor electrode 100 of the present invention comprises a transparent electrode 110 disposed onto the surface of a substrate (not shown), layer of metal oxide particles 130, a carbon nanotube 140 anchored on the metal oxide particles 130 through an anchoring functional group thereof, and a dye 150 adsorbed onto the metal oxide particles 130.

The transparent electrode 110 is formed by disposing a conductive material onto the surface of the substrate. As long as it is transparent, the choice of substrate is not specifically limited, and may be a transparent inorganic substrate such as quartz or glass, or a transparent polymeric substrate such as polyethylene terephthalate (PET), polyethylene naphthalate (PEN), polycarbonate, polystyrene, or polypropylene.

The conductive material disposed on the substrate may include, but is not limited to, tin-doped indium oxide (ITO), fluorine-doped tin oxide (FTO), ZnO—Ga₂O₃, ZnO—Al₂O₃, and SnO₂—Sb₂O₃.

The metal oxide particles 130 and the dye 150 adsorbed thereon form a light absorbing layer 160 of the semiconductor electrode. Desirably, the metal oxide particles 130 have a large surface area onto which the dye 150 is adsorbed, since the ability of the light absorbing layer 160 to absorb as much light energy as possible enables high efficiency. The surface area of the light absorbing layer 160 can be enlarged by using porous metal oxides.

In the present invention, the metal oxide particles 130 may comprise titanium oxide, tungsten oxide, niobium oxide, hafnium oxide, indium oxide, tin oxide, zinc oxide, or the like, or a combination comprising at least one of the foregoing. Exemplary metal oxides include TiO₂, SnO₂, ZnO, WO₃, Nb₂O₅, or TiSrO₃, with a greater preference for anatase-type TiO₂.

As for the metal oxide particles 130 of the light absorbing layer 160, their surface area is desirably enlarged not only to adsorb a greater amount of the dye 150 thereon, thereby absorbing more sunlight as described above, but also to improve adsorption to the electrolyte layer. Accordingly, it is desirably that the metal oxide particles 130 of the light absorbing layer 160 have a nanostructure, wherein each particle can take the form of a quantum dot, a nanodot, a nanotube, a nanowire, a nanobelt, a nanoparticle, or the like, or a combination comprising at least one of the foregoing.

Although not specifically limited, an average particle size of the metal oxide particles 130 can be about 1 to about 200 nanometers (nm), and more specifically about 5 to about 100 nm. Furthermore, it is also possible to mix two or more metal oxides having different particle sizes so as to scatter incident light and improve quantum efficiency.

As mentioned above, a carbon nanotube 140 with an anchoring functional group is attached to the surface of the metal oxide particles 130 through the anchoring functional group thereof. Any functional group, as long as it has affinity for a metal oxide, may be used as the anchoring functional groups. Examples thereof include, but are not limited to, carboxylic acid, phosphoric acid, sulfuric acid, and salicylic acid groups.

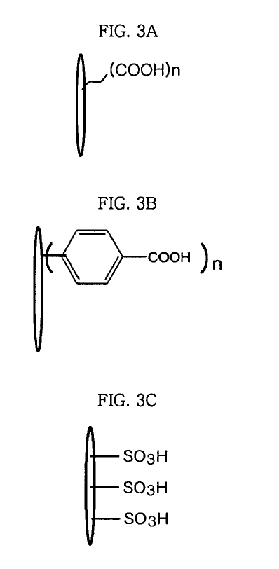

Referring now to FIGS. 3A to 3C, carbon nanotubes 140having various anchoring functional groups are shown. As seen in FIGS. 3A and 3B, one functional group may be connected to one carbon nanotube 140. Alternatively, as shown in FIG. 3C, two or more anchoring functional groups may be connected to one carbon nanotube 140. In this case, the plurality of anchoring functional groups may be the same or different from each other.

In accordance with the present invention, the carbon nanotube 140 may be selected from the group consisting of single-walled carbon nanotubes, multi-walled carbon nanotubes (e.g., double-walled carbon nanotubes, triple-walled carbon nanotubes, quadruple-walled carbon nanotubes, and the like), carbon nanohorns, carbon nanofibers, and combinations thereof.

The anchoring functional group can be conjugated to the carbon nanotube 140 using various processes depending on the kind thereof. Generally, the surface of the carbon nanotube (CNT) 140 is chemically modified to be more compatible with the anchoring functional group. Alternatively, the CNT 140 is cut to provide a truncated surface suitable for conjugation with anchoring functional groups.

Any material may be used as the dye 150, without limitation, as long as it has an electric charge separation function and is photosensitive. Exemplary dyes 150 include ruthenium complexes such as RuL₂(SCN)₂, RuL₂(H₂O)₂, RuL₃, and RuL₂ (wherein, L is 2,2′-bipyridyl-4,4′-dicarboxylate). In addition to ruthenium complexes, other exemplary dyes 150 include xanthine-based dyes such as rhodamine B, rose bengal, eosin, and erythrosine; cyanine-based dyes such as quinocyanine and cryptocyanine; basic dyes such as phenosafranine, capri blue, thiosine, and methylene blue; porphyrin-based compounds such as chlorophyll, zinc porphyrin, and magnesium porphyrin; azo dyes; phthalocyanine compounds; complex compounds such as ruthenium trisbipyridyl; anthraquinone-based dyes; polycyclic quinone-based dyes; or the like; or a combination comprising at least one of the foregoing dyes.

The semiconductor electrode 100 according to the present invention may be employed in photoelectrochromic devices and solar cell-operable display devices, as well as in various solar cells. Having high photoelectric conversion capacity, the semiconductor electrode 100 of the present invention can be used to implement highly efficient photoelectric conversion devices.

An exemplary embodiment of a method for manufacturing a semiconductor electrode 100 using a carbon nanotube 140 includes forming a layer of metal oxide particles 130 on a transparent electrode 110, followed by attaching a carbon nanotube 140 having an anchoring functional group to the surface of the layer of metal oxide particles 130 and then adsorbing the dye 150 onto the carbon nanotube-attached layer of metal oxide particles 130. As stated above, the anchoring functional group is selected from among a carboxylic group, a phosphoric group, a sulfuric group, a salicylic group, or like group. The method of manufacturing the semiconductor electrode is described in more detail below.

First, a layer of metal oxide particles 130 is formed on a transparent electrode 110 prepared by applying a conductive material to a transparent substrate.

The process for forming the layer of metal oxide particles 130 is not specifically limited, but may be preferably achieved using a wet process in consideration of physical properties, convenience, and production costs. In an exemplary embodiment, a paste is prepared by uniformly dispersing a metal oxide powder in a solvent. The paste is then disposed on the transparent electrode 110. Disposing the metal oxide paste may be accomplished using any known coating method, including for example, spraying, spin coating, dipping, printing, doctor blading, or sputtering, or using an electrophoresis process.

Generally, the disposing step is followed by a drying step and a sintering step, in that order. The drying step and the sintering step may be conducted at about 50 to about 100 degrees Celsius (° C.) and at about 400 to about 500° C., respectively.

Next, carbon nanotubes 140 having the anchoring functional groups capable of forming primary or secondary bonds to the metal oxide are dispersed in a suitable solvent. The dispersion is preferably facilitated using ultrasonication, a thermal treatment (e.g., heating), or a combination comprising at least one of the foregoing.

Exemplary solvents for the carbon nanotube dispersion include alcohols such as methanol, ethanol, isopropyl alcohol, propanol, butanol, and the like; ketones such as acetone, methylethyl ketone, ethyl isobutyl ketone, methyl isobutyl ketone, and the like; ethylene glycols such as ethylene glycol, ethylene glycol methyl ether, ethylene glycol mono-n-propylether, and the like; propylene glycols such as propylene glycol, propylene glycol methyl ether, propylene glycol ethyl ether, propylene glycol butyl ether, propylene glycol propyl ether, and the like; amides such as dimethylform amide, dimethyl acetamide, and the like; pyrrolidones such as N-methylpyrrolidone, N-ethylpyrrolidone, and the like; hydroxyesters such as dimethylsulfoxide, γ-butyrolactone, lactic acid methyl, lactic acid ethyl, β-methoxyisobutyric acid methyl, α-hydroxyisobutyric acid methyl, and the like; anilines such as aniline, N-methyl aniline, and the like; hexane; terpineol; chloroform; toluene; propylene glycol monomethyl ether acetate (PGMEA); N-methyl-2-pyrrolidone (MMP); or the like; or combinations comprising at least one of the foregoing.

The metal oxide-coated substrate is subsequently dipped in, or sprayed with, the dispersion of the carbon nanotubes 140 for a period of time sufficient to permit attachment of the carbon nanotubes 140 to the metal oxide-coated substrate.

After application (e.g., by dipping or spraying) of the carbon nanotube dispersion, the semiconductor electrode 100 may desirably be washed with the same solvent as is used to form the dispersion, so as to form a single layer of carbon nanotubes 140. If the carbon nanotubes 140 are layered to have a greater thickness like a multilayered structure, there might occur a problem in which the electrolyte does not penetrate into the dye well, or dye adsorption is impeded.

The layer of metal oxide particles 130 to which the carbon nanotubes 140 having anchoring functional groups are attached can be dipped in a photosensitive dye solution for about 12 hours or longer to adsorb the dye 150 on the surface of the metal oxide particles 130. Tertiary butyl alcohol, acetonitrile, or mixtures thereof may be used as a solvent for the photosensitive dye solution. Finally, after washing and drying the substrate, the semiconductor electrode 100 of the present invention is formed.

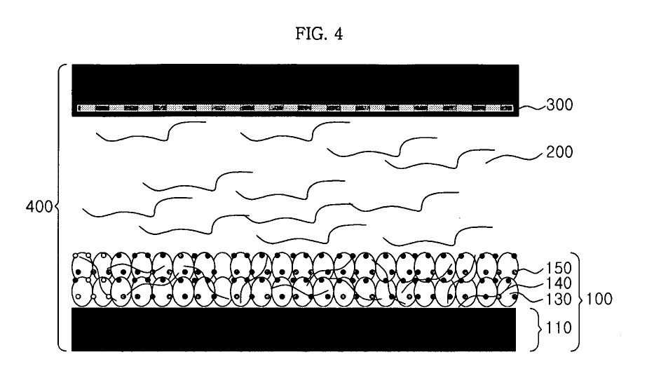

Referring now to FIG. 4, there is shown an exemplary embodiment of a dye-sensitized solar cell, generally designated 400, which includes the semiconductor electrode 100 of the present invention. The dye-sensitized solar cell 400 comprises the semiconductor electrode 100, an electrolyte layer 200 and a counter electrode 300. The counter electrode 300 is disposed opposite the semiconductor electrode 100, with the electrolyte layer 200 sandwiched therebetween. Without being bound by theory, it is believed that the solar cell 400 of the present invention is superior in photoelectric conversion efficiency because the semiconductor electrode 100 is designed to minimize or completely block the electron back-transfer and facilitate the migration of electrons to the counter electrode 300.

As long as it can function as a hole conductor, any electrolyte may be used without limitation. For example, the electrolyte layer 200 may comprise a solution of iodide in, for example, acetonitrile, N-methylpyrrolidone (NMP), or 3-methoxypropionate. Alternatively, a solid electrolyte such as triphenylmethane, carbazole, N,N′-diphenyl-N,N′-bis(3-methylphenyl)-1,1′-biphenyl)-4,4′-diamine (TPD), or the like may be used.

Any electrically conductive material may be used to produce the counter electrode 300. Even an insulating material may be used as long as the side thereof facing the semiconductor electrode 100 is covered with a layer of a conductive material. However, an electrochemically stable material is preferred as an electrode. Platinum, gold, carbon, or carbon nanotubes (CNT) are exemplary materials. The side of the counter electrode 300 facing the semiconductor electrode 100 desirably has a large surface area for increased catalytic oxidation/reduction capability. In an exemplary embodiment, the side of the counter electrode 300 facing the semiconductor electrode 100 has a microstructure. For example, the counter electrode 300 can be made from platinum black rather than from platinum itself. In the case of carbon, the counter electrode 300 will be porous.

The solar cell 400 of the present invention functions in the following manner. When sunlight is absorbed by the dye-containing semiconductor electrode 100, electrons of the dye molecules transition from the ground state to the excited state to form electron-hole pairs, and the electrons in the excited state are injected into the conduction band of the metal oxide. After being injected into the conduction band, the electrons are transferred to the counter electrode 300 with the concomitant production of electromotive force. While the electrons in the excited state jump to the conduction band of the metal oxide, the dye molecules losing the electrons receive electrons from the redox pairs or hole-transport materials of the electrolyte, so that the ground state is restored. The carbon nanotube 140 fixed to the metal oxide through the anchoring functional group thereof greatly improves the photoelectric conversion efficiency not only because it reduces the electron back-transfer between the metal oxide and the electrolyte 200, but also because it absorbs long-wavelength light to induce light harvesting.

To fabricate the dye-sensitized solar cell 400 according to the present invention any method known in the art may be used without restriction. The dye-sensitized solar cell 400 may be fabricated, for example, by arranging the semiconductor electrode 100 of the present invention and a counter electrode 300 opposite to each other, forming a closed space between the two electrodes, and injecting an electrolyte 200 into the closed space. For example, in an exemplary embodiment, a thermoplastic polymeric film (SURLYN, DuPont) having a thickness of about 40 micrometers (μm), is disposed between the counter electrode 300 and the semiconductor electrode 100, and the two electrodes were closely attached to the polymeric film using an adhesive such as epoxy resin, under conditions of heat and pressure.

A better understanding of the present invention may be obtained in light of the following examples which are set forth to illustrate, but are not to be construed to limit, the present invention.

### PREPARATION EXAMPLE 1

### Preparation of Carbon Nanotube Conjugated with Anchoring Functional Group

In an argon atmosphere, 20 milligrams (mg) of carbon nanotubes were added to a three-neck, round-bottom flask equipped with a dry ice condenser. Subsequently, 60 milliliters (mL) of ammonia were condensed within the flask and an 0.12 gram (g) strip of lithium was placed inside the flask. Afterwards, 6.4 millimoles (mmol) or 4 equivalents of 4-iodobenzoic acid were added, and the resulting mixture was stirred at −33° C. for 12 hours while the ammonia was slowly evaporated. Ethanol was slowly added, followed by quenching with water. Acidification with a 10% solution of hydrochloric acid, filtration through a 0.2 μm PTFE membrane, and washing with water and ethanol, in that order produced a 4-benzoic acid-conjugated carbon nanotube (CNT-(PhCOOH)ₙ).

### PREPRATION EXAMPLE 2

### Preparation of Carbon Nanotube Conjugated with Anchoring Functional Group

1.0 g of carbon nanotubes was dispersed in 200 mL of a 1 N sulfuric acid solution. The dispersion was placed in a two-neck flask equipped with a reflux condenser and a dropping funnel and then heated at 150° C. in an oil bath with vigorous stirring. A solution of 29.04 g of potassium permanganate in 200 mL of 1N sulfuric acid was added dropwise from the dropping funnel. After 5 hours of additional refluxing, the reaction mixture was quenched and filtered. The filtrate was washed with distilled water, concentrated HCl, and distilled water in order, and dried to give carboxyl group-conjugated carbon nanotubes (CNT-(COOH)ₙ).

### EXAMPLE 1

A glass substrate was sputtered with fluorine-doped tin oxide (FTO), and then coated with a paste of TiO₂ particles, having an average particle size of 13 nm, using a screen printing method. Drying at 70° C. for 30 minutes was followed by sintering at 500° C. for 60 minutes in an electric furnace to produce a porous TiO₂ membrane having a thickness of about 15 μm, on the glass substrate.

4 mg of the CNT-(PhCOOH)ₙ were dispersed in 15 ml of ethanol and subjected to ultrasonification (SONOREX RK 106, 35 kilohertz, 240 Watts, Bandelin Electronic, Germany) for 1 hour in a water bath maintained at 50° C to produce a carbon nanotube solution.

The glass substrate with the TiO₂ layer formed thereon was immersed for 5 minutes in the carbon nanotube solution. After completion of the attachment of the carbon nanotubes, the glass substrate was immersed for 24 hours in a solution of cis-bis(isothiocyanato)-bis(2,2-bypyridyl-4,4′-dicarboxylato)-ruthenium (II) (“N3 dye”) in ethanol so as to adsorb the dye onto the TiO₂ layer. The dye-adsorbed electrode thus obtained was washed with ethanol and dried to produce a semiconductor electrode.

### EXAMPLES 2 TO 4

The procedure as described in EXAMPLE 1 was repeated, with the exception that the glass substrate with a TiO₂ layer formed thereon was immersed for 1.5 hours (EXAMPLE 2), 3 hours (EXAMPLE 3), and 24 hours (EXAMPLE 4) in the anchoring functional group-conjugated carbon nanotube solution, to produce various semiconductor electrodes.

### EXAMPLE 5

The procedure described in EXAMPLE 2 was repeated, with the exception of using CNT-(COOH)ₙ, instead of CNT-(PhCOOH)ₙ, to produce the semiconductor electrode.

### EXAMPLES 6 TO 10

Platinum was sputtered on a tin-doped indium oxide (ITO)-coated glass substrate so as to produce a counter electrode. Each of the semiconductor electrodes produced in Examples 1 to 5, serving as a cathode, was assembled with the counter electrode as an anode in such a way that the platinum layer of the counter electrode faced the dye-adsorbed metal oxide layer of the semiconductor electrode. A 100 μm thick SURLYN film (Du Pont) was placed between the counter electrode and the semiconductor electrode , and the two electrodes were closely attached onto the polymeric film under a pressure of about 1 to about 3 atmospheres (atm) on a heating plate heated to about 120° C.

Afterwards, an electrolyte was injected into the space between the two electrodes to complete the fabrication of a dye-sensitized solar cell. The electrolyte was an I₃⁻/I⁻ solution containing 0.6 moles per liter (M) 1,2-dimethyl-3-octyl imidazolium iodide, 0.2M LiI, 0.04 M I₂, and 0.2 M 4-tert-butyl pyridine (TBP) in acetonitrile.

### COMPARATIVE EXAMPLE 1

A solar cell was fabricated in a manner similar to that of EXAMPLE 6, with the exception that the metal oxide layer of the semiconductor electrode had the dye adsorbed thereon, but did not include any carbon nanotubes.

### EXPERIMENTAL EXAMPLE 1

### Measurement of Solar Cell for Photoelectric Conversion Efficiency

Solar cells fabricated in EXAMPLES 6 to 10 and COMPARATIVE EXAMPLE 1 were evaluated for photoelectric conversion efficiency by measuring photovoltages and photocurrents thereof. A xenon lamp (Oriel, 01193) was used as a light source. The spectral irradiance was corrected to the AM 1.5 standard with a reference solar cell (Furnhofer Institute Solare Engeriessysteme, Certificate No. C-ISE369, Type of material: Mono-Si⁺ KG filter). After being calculated from photocurrent-voltage curves, current densities (I_{sc}), open circuit voltages (V_{oc}) and fill factors (FF) were used to obtain photoelectric conversion efficiencies (ηₑ) of the solar cells using Mathematic Formula 1. The results are summarized in Table 1, below.

ηₑ=(V_{oc}·I_{sc}·FF)/(P_{inc}) [Mathematic Formula 1]:

wherein P_{inc} is expressed in units of 100 mw/cm² (1 sun).

TABLE 1

| Example Nos. | I_{sc}(mA/cm²) | V_{oc}(mV) | FF | ηₑ(%) |
|---|---|---|---|---|
| Example 6 | 9.729 | 667 | 0.628 | 4.074 |
| Example 7 | 9.895 | 673 | 0.640 | 4.260 |
| Example 8 | 9.8798 | 689 | 0.625 | 4.386 |
| Example 9 | 9.574 | 689 | 0.625 | 4.121 |
| Example 10 | 9.805 | 634 | 0.580 | 3.601 |
| Comparative Example | 9.204 | 656 | 0.562 | 3.393 |

Taken together, the data shown in Table 1, obtained from the various samples tested, demonstrate that the dye-sensitized solar cells employing the semiconductor electrode according to the present invention have greatly improved photoelectric conversion efficiency. The improved conversion efficiency can be attributed to the fact that the semiconductor electrodes undergo less electron back-transfer and that the carbon nanotubes absorb long wavelength light.

As described hereinabove, the semiconductor electrode according to the present invention undergoes decreased electron back-transfer owing to the carbon nanotubes anchored at the metal oxide layer, leading to an increase in photocurrent density (I_{sc}) and thus in photoelectric conversion efficiency. Accordingly, the semiconductor electrode of the present invention enables highly efficient solar cells.

Although the present invention has been described with reference to the foregoing exemplary embodiments, these exemplary embodiments do not serve to limit the scope of the present invention. Accordingly, those skilled in the art to which the present invention pertains will appreciate that various modifications, additions and substitutions are possible, without departing from the scope and spirit of the accompanying claims.

What is claimed is:

1. A semiconductor electrode, comprising:
a layer of metal oxide particles;
a dye coating a surface of the layer of metal oxide particles; and
a carbon nanotube, having at least one anchoring functional group, attached to the layer of metal oxide particles through the anchoring functional group.

2. The semiconductor electrode as set forth in claim 1, wherein the at least one anchoring functional group is selected from the group consisting of a carboxylic acid group, a phosphoric acid group, a sulfuric acid group, a salicylic acid group, and combinations thereof.

3. The semiconductor electrode as set forth in claim 1, wherein the carbon nanotube is selected from the group consisting of a single-walled carbon nanotube, a double-walled carbon nanotube, a triple-walled carbon nanotube, a quadruple-walled carbon nanotube, a carbon nanohorn, and a carbon nanofiber.

4. The semiconductor electrode as set forth in claim 1, wherein the layer of metal oxide particles comprises titanium oxide, tungsten oxide, niobium oxide, hafnium oxide, indium oxide, tin oxide, zinc oxide, or a combination comprising at least one of the foregoing.

5. The semiconductor electrode as set forth in claim 1, wherein the dye is selected from the group consisting of ruthenium complexes, xanthine-based dyes, cyanine-based dyes, basic dyes, porphyrin-based compounds, complex compounds, anthraquinone-based dyes, polycyclic quinone-based dyes, and combinations thereof.

6. The semiconductor electrode as set forth in claim 1, wherein the layer of metal oxide particles has a nanostructure comprising a quantum dot, a nanodot, a nanotube, a nanowire, a nanobelt, a nanoparticle, or a combination comprising at least one of the foregoing.

7. A method for preparing a semiconductor electrode, comprising:
forming a layer of metal oxide particles on a transparent electrode;
attaching a carbon nanotube having at least one anchoring functional group to a surface of the layer of metal oxide particles, wherein the at least one anchoring functional group is selected from the group consisting of a carboxylic acid group, a phosphoric acid group, a sulfuric acid group, a salicylic acid group, and combinations thereof; and
adsorbing a dye on a surface of the layer of metal oxide particles.

8. The method as set forth in claim 7, wherein the attaching the carbon nanotube comprises:
dispersing the carbon nanotube having the anchoring functional group in a solvent; and
immersing in the dispersion of the carbon nanotube the transparent electrode with the layer of metal oxide particles formed thereon.

9. The method as set forth in claim 8, wherein dispersing the carbon nanotube in the solvent is facilitated using ultrasonication, a thermal treatment, or a combination comprising at least one of the foregoing.

10. The method as set forth in claim 8, wherein the solvent is selected from the group consisting of alcohols, ketones, ethylene glycols, propylene glycols, amides, pyrrolidones, hydroxyesters, anilines, hexane, terpineol, chloroform, toluene, propylene glycol monomethyl ether acetate, N-methyl-2-pyrrolidone, and combinations thereof.

11. A solar cell, comprising:
a semiconductor electrode comprising a transparent electrode in which a conductive material is disposed on a substrate; a layer of metal oxide particles disposed on the transparent electrode; a carbon nanotube anchored on a surface of the layer of metal oxide particles through at least one anchoring functional group conjugated thereto, wherein the at least one anchoring functional group is selected from the group consisting of a carboxylic acid group, a phosphoric acid group, a sulfuric acid group, a salicylic acid group, and combinations thereof; and a dye adsorbed on the layer of metal oxide particles;
a counter electrode arranged opposite the semiconductor electrode; and
an electrolyte disposed between the semiconductor electrode and the counter electrode.

12. The solar cell as set forth in claim 11, wherein the carbon nanotube is selected from the group consisting of a single-walled carbon nanotube, a double-walled carbon nanotube, a triple-walled carbon nanotube, a quadruple-walled carbon nanotube, a carbon nanohorn, and a carbon nanofiber.
